(19) United States
(12) Patent Application Publication
(10) Pub. No.: US 2026/0059646 A1
(43) Pub. Date: Feb. 26, 2026

(54) CIRCUIT BOARD AND MANUFACTURING METHOD THEREOF

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (TW)

(72) Inventor: Cheng-Jia LI, Shenzhen (CN)

(21) Appl. No.: 18/811,183

(22) Filed: Aug. 21, 2024

(51) Int. Cl. H05K 1/02; H05K 3/12; H05K 3/30; H05K 3/40

(52) U.S. Cl. CPC H05K 1/0204; H05K 3/1208; H05K 3/305; H05K 3/4007; H05K 2201/0281; H05K 2201/0311; H05K 2201/0367; H05K 2201/066; H05K 2201/083; H05K 2203/308

(57) ABSTRACT

A circuit board includes a wiring base including pads, a temperature control element, flexible parts, conductive pillars and an electronic component disposed on the temperature control element. The temperature control element is disposed on the wiring base, forms a gap with the wiring base, and includes a first memory metal layer, a second memory metal layer fixed on the first memory metal layer, first magnetic attraction parts disposed in the first memory metal layer, and second magnetic attraction parts disposed in the second memory metal layer and corresponding to the first magnetic attraction parts, respectively. The flexible parts are disposed in the gap and correspond to the first magnetic attraction parts, respectively, and are electrically connected to the pads, respectively. The conductive pillars are disposed between the electronic component and the temperature control element, penetrate the second magnetic attraction parts, respectively, and are electrically connected to the electronic component.

### BACKGROUND

### Field of Invention

The present disclosure relates to a circuit board and a method of manufacturing the same.

### Description of Related Art

When the electronic component of a circuit board is subjected to increased voltage, current and operating time, the heat generated by the electronic component also increases, and the heat dissipation path is mainly from the surface of the electronic component to the surrounding environment. However, with the emergence of electronic products with high-density and thinner assembly, the small surface area of the electronic components is no longer sufficient for effective dissipation of heat. In addition, a large proportion of heat generated by the electronic component may also be transferred to the circuit board, thereby causing the circuit board, or the electronic component at the location where the heat accumulates, to fail. This would result in decreased reliability and a shortened life of the product.

### SUMMARY

At least one embodiment of the present disclosure provides a circuit board that can protect against overheating. This can be done through a temperature control element to reduce the damages caused by high temperatures, thereby contributing to improve reliability and also increase product life.

At least another embodiment of the present disclosure provides a method of manufacturing the abovementioned circuit board. The method helps the above-mentioned circuit board provide the overheat protection function through a temperature control element to reduce the damages caused by high temperatures, thereby contributing to improve reliability and also increase product life.

The circuit board according to at least one embodiment of the present disclosure includes a wiring base, a temperature control element, multiple flexible parts, an electronic component and multiple conductive pillars. The wiring base includes multiple pads. The temperature control element is disposed on the wiring base and forms a gap with the wiring base. The temperature control element includes a first memory metal layer, a second memory metal layer, multiple first magnetic attraction parts and multiple second magnetic attraction parts. The second memory metal layer is fixed on the first memory metal layer, where the first memory metal layer is located between the second memory metal layer and the wiring base. The first magnetic attraction parts are disposed in the first memory metal layer. The second magnetic attraction parts are disposed in the second memory metal layer and correspond to the first magnetic attraction parts, respectively. The flexible parts are disposed in the gap and correspond to the first magnetic attraction parts, respectively. The flexible parts are electrically connected to the pads, respectively. The electronic component is disposed on the temperature control element. The conductive pillars are disposed between the electronic component and the temperature control element, where the conductive pillars penetrate the second magnetic attraction parts, respectively, and are electrically connected to the electronic component.

The method of manufacturing the circuit board according to at least another embodiment of the present disclosure includes the following steps. A first sacrificial layer and a conductive layer are provided, where the first sacrificial layer is located on the conductive layer. The first sacrificial layer is patterned to form multiple first trenches. Multiple conductive portions are formed in the first trenches. After the conductive portions are formed, the conductive layer is patterned to form multiple pads. After the pads are formed, a build-up structure is laminated on the pads and the build-up structure is patterned to form multiple second trenches. Multiple wiring structures are formed in the second trenches. After the wiring structures are formed, the first sacrificial layer is removed to expose a sidewall of each of the conductive portions. After the first sacrificial layer is removed, multiple outer portions surrounding the conductive portions, respectively, are formed to form multiple flexible parts. A second sacrificial layer is formed to surround the flexible parts. Multiple first magnetic attraction parts corresponding to the flexible parts, respectively, and a third magnetic attraction part located on the second sacrificial layer are formed. A first memory metal layer on the second sacrificial layer to surround the first magnetic attraction parts and the third magnetic attraction part is formed. After the first memory metal layer is formed, the second sacrificial layer is removed to form a gap. An initial connecting layer and a second initial memory metal layer are provided, where the initial connecting layer is located on the second initial memory metal layer. The initial connecting layer and the second initial memory metal layer are patterned to form a connecting layer and a second memory metal layer, where the connecting layer has multiple grooves and the second memory metal layer has multiple openings. Multiple second magnetic attraction parts and a fourth magnetic attraction part are formed in the openings. After the second magnetic attraction parts and the fourth magnetic attraction part are formed, an electronic component is adhered to the connecting layer. After the electronic component is adhered to the connecting layer, the second memory metal layer is disposed on the first memory metal layer to make the first magnetic attraction parts and the second magnetic attraction parts be attracted to each other and be in contact with each other, and the third magnetic attraction part and the fourth magnetic attraction part be attracted to each other and be in contact with each other.

It is to be understood that both the foregoing general descriptions and the following detailed descriptions are by examples, and are intended to provide further explanation of the present disclosure as claimed.

### BRIEF DESCRIPTION OF THE DRAWINGS

The present disclosure can be more fully understood by reading the following detailed description of the embodiments, with reference made to the accompanying drawings as follows:

FIG. 1A and FIG. 1B are partial schematic cross-sectional views of a circuit board in a contact state and a separated state, respectively, as according to at least one embodiment of the present disclosure.

FIGS. 2A to 2R are partial schematic cross-sectional views of the circuit board as shown in FIG. 1A and FIG. 1B, at different manufacturing stages.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface as shown in the drawings may have rough and/or non-linear characteristics, and the acute angle as shown in the drawings may be round. Therefore, the elements presented in the drawings in this case are mainly for illustrative purposes, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular”, where “substantially parallel” and “substantially perpendicular” mean that parallelism and perpendicularity, respectively, between the two objects can include non-parallelism and non-perpendicularity caused by permissible deviation ranges.

The spatial relative terms used in the present disclosure, such as “below”, “under”, “above”, “on”, and the like, are intended to facilitate the recitation of a relative relationship between one element or feature and another as depicted in the figures. The true meaning of these spatial relative terms includes other orientations. For example, the relationship between one element and another may change from “below” and “under” to “above” and “on” when the figure is turned 180 degrees up or down. In addition, spatially relative descriptions used in the present disclosure should be interpreted in the same manner.

It should be understood that while the present disclosure may use terms such as “first”, “second”, “third”, etc. to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Although a series of operations or steps are used to illustrate the manufacturing method in the present disclosure, the order shown in these operations or steps should not be construed as a limitation of the present disclosure. For example, some operations or steps may be performed in a different order and/or concurrently with other steps. In addition, each operation or step described herein may include several sub-steps or actions.

Moreover, the present disclosure may be implemented or applied in various other specific embodiments, and the details of the present disclosure may be combined, modified, and altered in various embodiments based on different viewpoints and applications, without departing from the idea of the present disclosure.

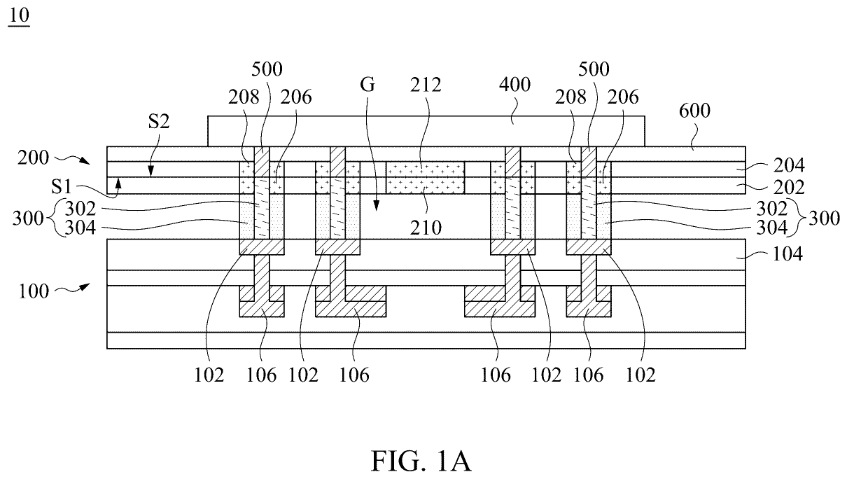

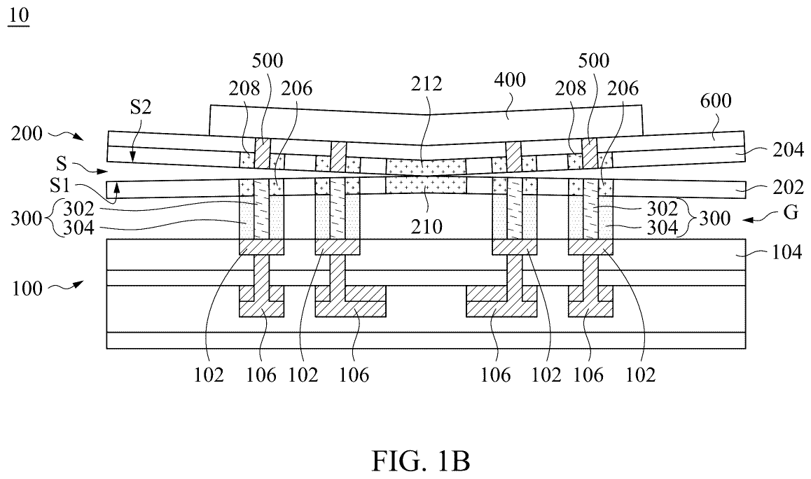

FIG. 1A and FIG. 1B are partial schematic cross-sectional views of a circuit board 10 in a contact state and a separated state, respectively, according to at least one embodiment of the present disclosure. Referring to FIG. 1A and FIG. 1B, the circuit board 10 includes a wiring base 100, a temperature control element 200, multiple flexible parts 300, an electronic component 400 and multiple conductive pillars 500.

The wiring base 100 includes multiple pads 102. The temperature control element 200 is disposed on the wiring base 100 and forms a gap G with the wiring base 100. The temperature control element 200 includes a first memory metal layer 202, a second memory metal layer 204, multiple first magnetic attraction parts 206 and multiple second magnetic attraction parts 208. The second memory metal layer 204 is fixed on the first memory metal layer 202, where the first memory metal layer 202 is located between the second memory metal layer 204 and the wiring base 100.

The first magnetic attraction parts 206 are disposed in the first memory metal layer 202. The second magnetic attraction parts 208 are disposed in the second memory metal layer 204 and correspond to the first magnetic attraction parts 206, respectively. The flexible parts 300 are disposed in the gap G and correspond to the first magnetic attraction parts 206, respectively, where the flexible parts 300 are electrically connected to the pads 102, respectively. The electronic component 400 is disposed on the temperature control element 200. The conductive pillars 500 are disposed between the electronic component 400 and the temperature control element 200, where the conductive pillars 500 penetrate the second magnetic attraction parts 208, respectively, and are electrically connected to the electronic component 400.

The temperature control element 200 can form a circuit break between the electronic component 400 having an excessive temperature and the pad 102 of the wiring base 100 to protect against overheating and reduce the damages caused by high temperatures, thereby contributing to improve reliability and increase product life.

Referring to FIG. 1A and FIG. 1B, the temperature control element 200 further includes a third magnetic attraction part 210 and a fourth magnetic attraction part 212. The third magnetic attraction part 210 is disposed in the first memory metal layer 202 and is located between two adjacent first magnetic attraction parts 206, and the width of the third magnetic attraction part 210 is greater than the width of each of the first magnetic attraction parts 206. The fourth magnetic attraction part 212 is disposed in the second memory metal layer 204 and is located between two adjacent second magnetic attraction parts 208, and the width of the fourth magnetic attraction part 212 is greater than the width of each of the second magnetic attraction parts 208. The third magnetic attraction part 210 and the fourth magnetic attraction part 212 are mutually attracted to each other and are in contact with each other, so that the second memory metal layer 204 is fixed on the first memory metal layer 202.

In some embodiments, the third magnetic attraction part 210 corresponds to the fourth magnetic attraction part 212. In detail, in the normal line of the wiring base 100, the third magnetic attraction part 210 overlaps with the fourth magnetic attraction part 212, and the first magnetic attraction parts 206 overlap with the second magnetic attraction parts 208, respectively. The orthographic projection area of the third magnetic attraction part 210 on the wiring base 100 is greater than the orthographic projection area of each of the first magnetic attraction parts 206 on the wiring base 100, and the orthographic projection area of the fourth magnetic attraction part 212 on the wiring base 100 is greater than the orthographic projection area of each of the second magnetic attraction parts 208 on the wiring base 100. In addition, the transformation temperature of the first memory metal layer 202 and the transformation temperature of the second memory metal layer 204 are substantially the same, and the bending direction of the first memory metal layer 202 and the bending direction of the second memory metal layer 204 are substantially opposite.

As shown in FIG. 1A, when the temperature of the circuit board 10 has not substantially reached the transformation temperature of the first memory metal layer 202 and the transformation temperature of the second memory metal layer 204, the second memory metal layer 204 is not bent relative to the first memory metal layer 202, and the first memory metal layer 202 and the second memory metal layer 204 are in contact with each other, so that the first magnetic attraction parts 206 and the second magnetic attraction parts 208 are attracted to each other and are in contact with each other, and the conductive pillars 500 are in contact with the flexible parts 300, respectively.

In detail, the first memory metal layer 202 and the second memory metal layer 204 have a first surface S1 and a second surface S2, respectively, facing each other. The first magnetic attraction parts 206 and the third magnetic attraction part 210 are exposed on the first surface S1, and the second magnetic attraction parts 208 and the fourth magnetic attraction part 212 are exposed on the second surface S2. When the second memory metal layer 204 is not bent relative to the first memory metal layer 202, the first surface S1 and the second surface S2 are in contact with each other, so that the first magnetic attraction parts 206 and the second magnetic attraction parts 208 are mutually attracted to each other and are in contact with each other. In addition, the third magnetic attraction part 210 and the fourth magnetic attraction part 212 are mutually attracted to each other and are in contact with each other. Furthermore, the conductive pillars 500 and the flexible parts 300 are in contact with each other to enable the electrical connection of the electronic component 400 to the pads 102 of the wiring base 100. As a result, the electronic component 400 is in a normal operating state.

As shown in FIG. 1B, when the temperature of the circuit board 10 has substantially reached the transformation temperature of the first memory metal layer 202 and the transformation temperature of the second memory metal layer 204, the second memory metal layer 204 is bent relative to the first memory metal layer 202, and the first memory metal layer 202 and the second memory metal layer 204 are partially separated, so that the first magnetic attraction parts 206 and the second magnetic attraction parts 208 are separated from each other, and the conductive pillars 500 are separated from the flexible parts 300.

In detail, when the second memory metal layer 204 is bent relative to the first memory metal layer 202, a space S is formed between the first surface S1 and the second surface S2, so that the first magnetic attraction parts 206 and the second magnetic attraction parts 208 are separated from each other, and the conductive pillars 500 are separated from the flexible parts 300, resulting in the electrical disconnection of the electronic component 400 from the pads 102 of the wiring base 100. As a result, the electronic component 400 is in a power-off state.

Since the force exerted by bending of the first memory metal layer 202 and the second memory metal layer 204 is greater than the mutual magnetic attraction force between the first magnetic attraction parts 206 and the second magnetic attraction parts 208, therefore the first magnetic attraction parts 206 and the second magnetic attraction parts 208 become separated from each other. However, since the widths of the third magnetic attraction part 210 and the fourth magnetic attraction part 212 are greater than the widths of each of the first magnetic attraction parts 206 and each of the second magnetic attraction parts 208, respectively, and the orthographic projection areas of the third magnetic attraction part 210 and the fourth magnetic attraction part 212 on the wiring base 100 are greater than the orthographic projection areas of each of the first magnetic attraction parts 206 and each of the second magnetic attraction parts 208 on the wiring base 100, respectively. Therefore, the magnetic attraction force between the third magnetic attraction part 210 and the fourth magnetic attraction part 212 is greater than the bending separation force between the first memory metal layer 202 and the second memory metal layer 204, thereby keeping the second memory metal layer 204 fixed on the first memory metal layer 202 through the mutual attractive force and the resulting contact formed between the third magnetic attraction part 210 and the fourth magnetic attraction part 212.

Accordingly, when the circuit board 10 is overheated, as shown in FIG. 1B, the first memory metal layer 202 and the second memory metal layer 204 are bent and partially separated to separate the first magnetic attraction parts 206 from the second magnetic attraction parts 208, and also to separate the conductive pillars 500 from the flexible parts 300, so that the electronic component 400 electrically disconnects from the pad 102 of the wiring base 100 and is in a power-off state, hence activating the overheating protection function. When the circuit board 10 returns to normal temperature, as shown in FIG. 1A, the first memory metal layer 202 and the second memory metal layer 204 are no longer bent and are in contact with each other, so that the first magnetic attraction parts 206 and the second magnetic attraction parts 208 are attracted to each other and are in contact with each other, the conductive pillars 500 and the flexible parts 300 are also in contact with each other, and thus the electronic component 400 becomes electrically connected to the pads 102 of the wiring base 100 and is in a normal operating state. Therefore, in this way the damages caused by high temperature can be reduced, thereby contributing to improve reliability and increase product life.

Referring to FIG. 1A and FIG. 1B, the circuit board 10 further includes a connecting layer 600 disposed between the temperature control element 200 and the electronic component 400, where the conductive pillars 500 penetrate the connecting layer 600. The wiring base 100 further includes an insulating layer 104 and multiple wiring structures 106, where the pads 102 and a portion of the wiring structures 106 are embedded in the insulating layer 104, and the top surface of each pad 102 is flush with the top surface of the insulating layer 104. In addition, each flexible part 300 includes a conductive portion 302 and an outer portion 304 surrounding the conductive portion 302, where the conductive portions 302 penetrate the first magnetic attraction parts 206, respectively, and are electrically connected to the pads 102, respectively.

In some embodiments, the materials of the insulating layer 104 and the connecting layer 600 may include resins, such as prepreg. The materials of the first memory metal layer 202 and the second memory metal layer 204 may include nickel-titanium alloys. The materials of the flexible parts 300 may include conductive fibers. The materials of the pads 102 and the conductive pillars 500 may include metals, such as copper. The electronic component 400 may be a chip.

In addition, the materials of the first magnetic attraction parts 206, the second magnetic attraction parts 208, the third magnetic attraction part 210 and the fourth magnetic attraction part 212 may include ferromagnetic materials or ferrimagnetic materials. In some embodiments, one of the first magnetic attraction part 206 and the second magnetic attraction part 208 is a magnet (such as a permanent magnet), and the other of the first magnetic attraction part 206 and the second magnetic attraction part 208 is not a magnet. Furthermore, one of the third magnetic attraction part 210 and the fourth magnetic attraction part 212 is a magnet (such as a permanent magnet), and the other of the third magnetic attraction part 210 and the fourth magnetic attraction part 212 is not a magnet. In other embodiments, the first magnetic attraction part 206 and the second magnetic attraction part 208 are both magnets, and the third magnetic attraction part 210 and the fourth magnetic attraction part 212 are both magnets.

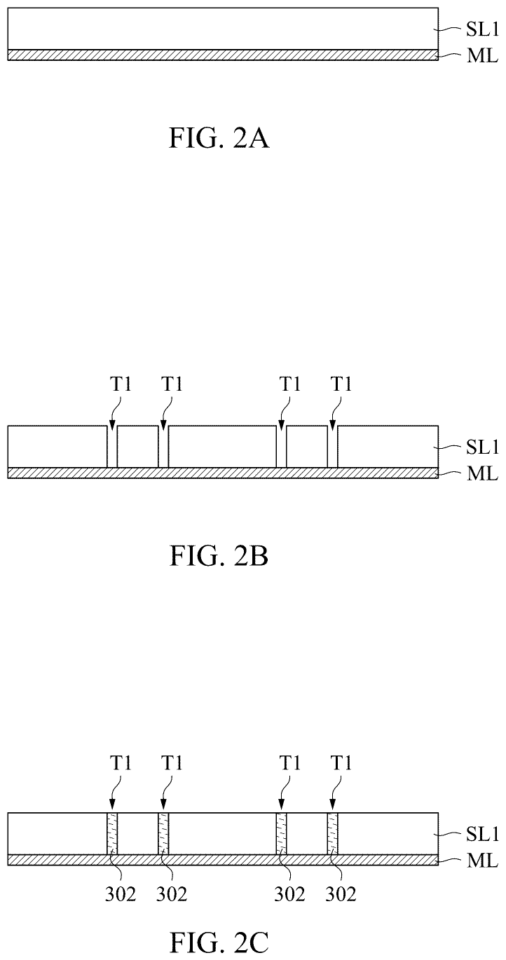

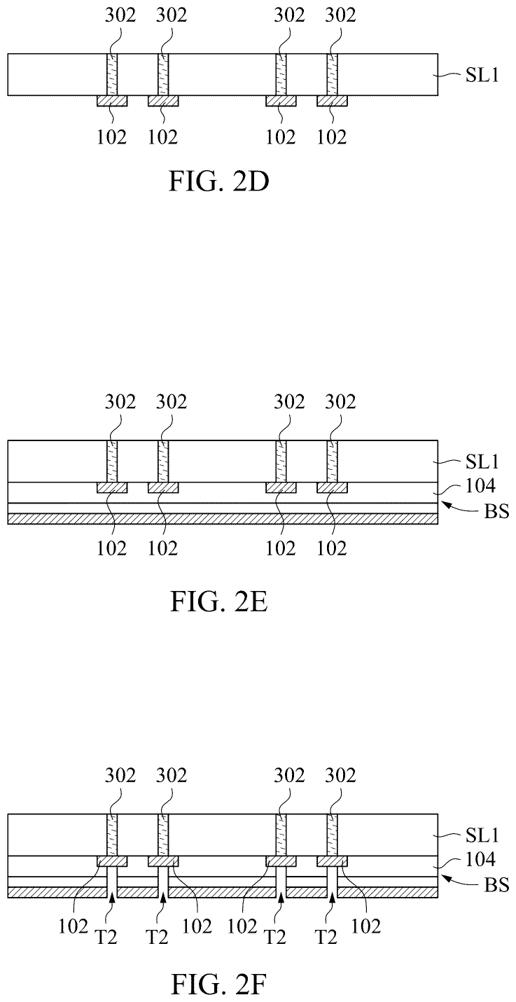

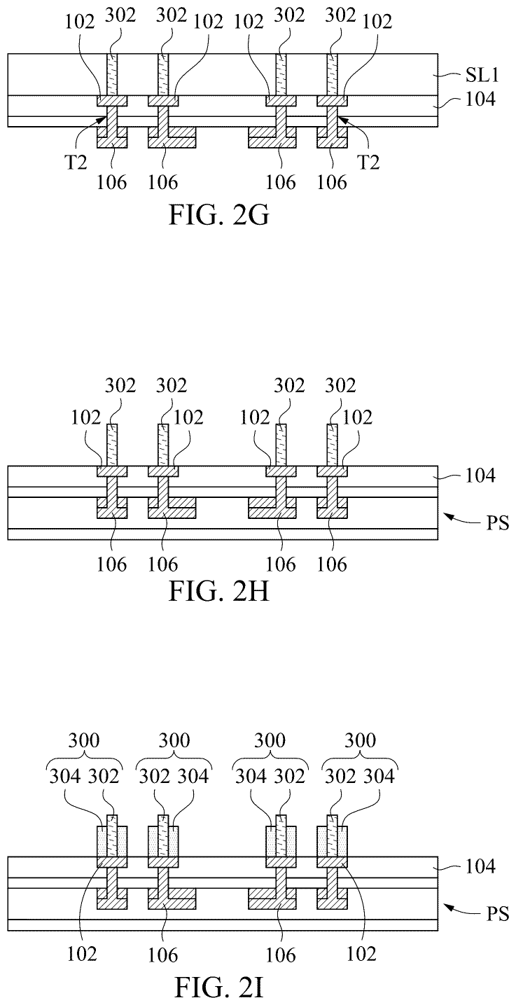

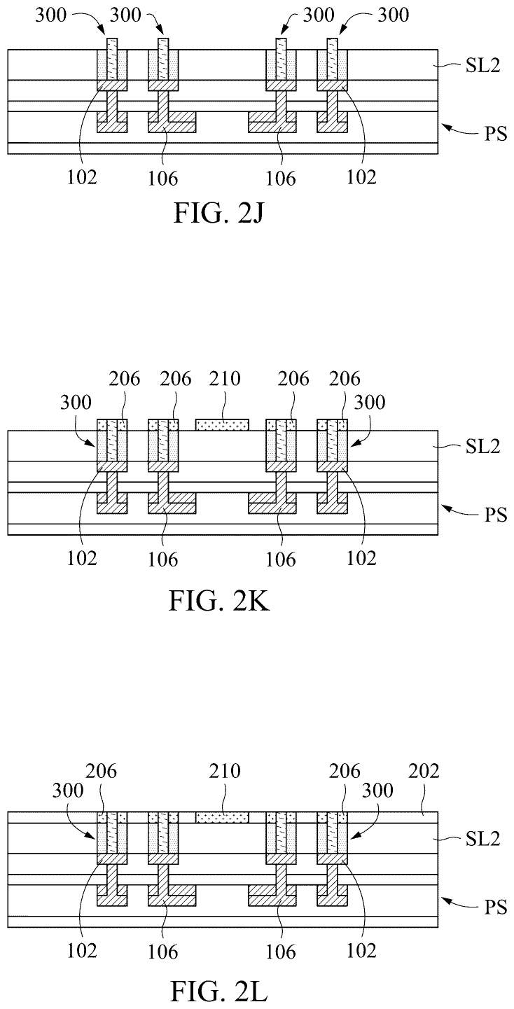

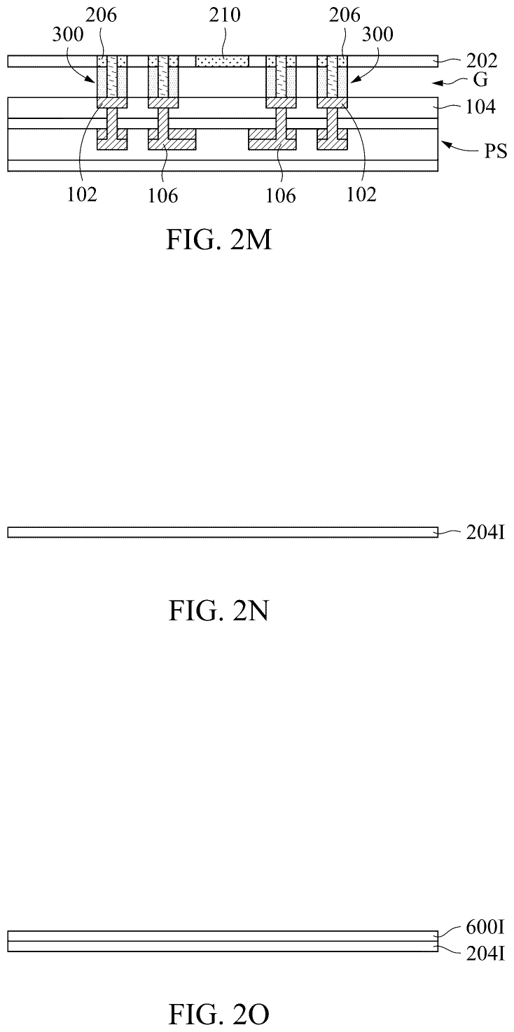

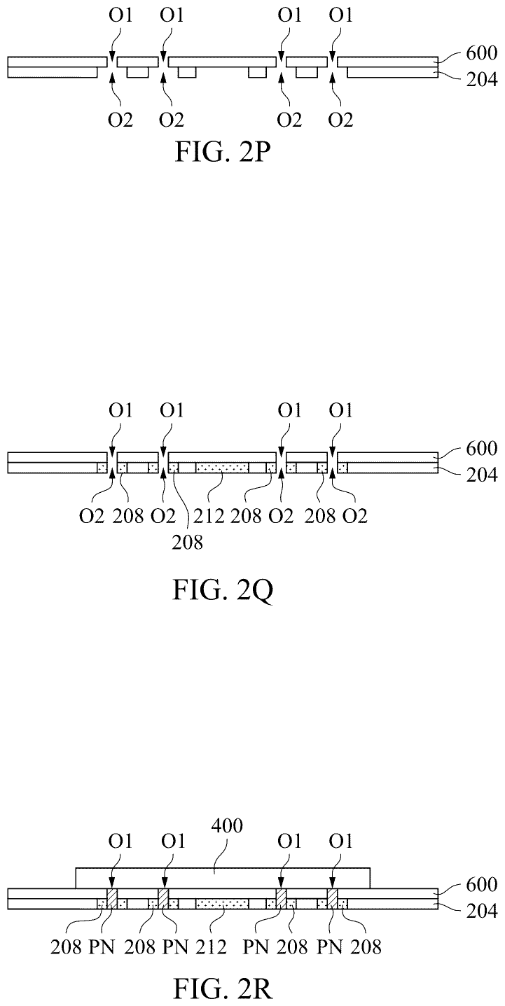

FIGS. 2A to 2R are partial schematic cross-sectional views of the circuit board as shown in FIG. 1A and FIG. 1B, at different manufacturing stages. First, referring to FIG. 2A, a first sacrificial layer SL1 and a conductive layer ML are provided, where the first sacrificial layer SL1 is located on the conductive layer ML. Next, referring to FIG. 2B, the first sacrificial layer SL1 is patterned to form multiple first trenches T1. In some embodiments, patterning the first sacrificial layer SL1 may be implemented by a laser process.

Referring to FIG. 2C, multiple conductive portions 302 are formed in the first trenches T1. Referring to FIG. 2D, after the conductive portions 302 are formed, the conductive layer ML is patterned to form multiple pads 102. Next, referring to FIG. 2E and FIG. 2F, after the pads 102 are formed, a build-up structure BS is laminated on the pads 102, and the build-up structure BS is patterned to form multiple second trenches T2. In some embodiments, the build-up structure BS includes an insulating layer 104. Forming the conductive portions 302 can be implemented by a printing process, patterning the conductive layer ML can be implemented by an etching process, and patterning the build-up structure BS can be implemented by a laser process.

Referring to FIG. 2G, multiple wiring structures 106 are formed in the second trenches T2. Referring to FIG. 2H, after the wiring structures 106 are formed, the first sacrificial layer SL1 is removed to expose the sidewalls of the conductive portions 302. In some embodiments, as shown in FIG. 2H, before the first sacrificial layer SL1 is removed, a protection structure PS may be formed on the wiring structures 106. In addition, forming the wiring structures 106 can be implemented by an electroplating process and an etching process.

Referring to FIG. 2I, after the first sacrificial layer SL1 is removed, multiple outer portions 304 respectively surrounding the sidewalls of the conductive portions 302 are formed to form multiple flexible parts 300. Next, referring to FIG. 2J, a second sacrificial layer SL2 is formed to surround the flexible parts 300. In some embodiments, forming the outer portions 304 and forming the second sacrificial layer SL2 may be implemented by a printing process.

Referring to FIG. 2K, multiple first magnetic attraction parts 206 respectively corresponding to the flexible parts 300 and a third magnetic attraction part 210 located on the second sacrificial layer SL2 are formed. Next, referring to FIG. 2L, a first memory metal layer 202 is formed on the second sacrificial layer SL2 to surround the first magnetic attraction parts 206 and the third magnetic attraction part 210. In some embodiments, forming the first magnetic attraction parts 206 and the third magnetic attraction part 210 and forming the first memory metal layer 202 can be implemented by a printing process.

Referring to FIG. 2M, after the first memory metal layer 202 is formed, the second sacrificial layer SL2 is removed to form a gap G. Next, referring to FIG. 2N and FIG. 2O, an initial connecting layer 600I and a second initial memory metal layer 204I are provided, where the initial connecting layer 600I is located on the second initial memory metal layer 204I. In some embodiments, forming the initial connecting layer 600I on the second initial memory metal layer 204I can be implemented by a lamination process.

Referring to FIG. 2P, the initial connecting layer 600I and the second initial memory metal layer 204I are patterned to form the connecting layer 600 and the second memory metal layer 204, where the connecting layer 600 has multiple grooves O1, and the second memory metal layer 204 has multiple openings O2. Next, referring to FIG. 2Q, multiple second magnetic attraction parts 208 and a fourth magnetic attraction part 212 are formed in the openings O2. In some embodiments, patterning the initial connecting layer 600I and the second initial memory metal layer 204I can be implemented by a laser process, and forming the second magnetic attraction parts 208 and the fourth magnetic attraction part 212 can be implemented by a printing process.

Referring to FIG. 2R, after the second magnetic attraction parts 208 and the fourth magnetic attraction part 212 are formed, the electronic component 400 is adhered to the connecting layer 600, and the electronic component 400 includes multiple pins PN. The pins PN are respectively inserted into the grooves O1 and penetrate the second magnetic attraction parts 208, respectively. In some embodiments, the electronic component 400 may not include the pins PN, but instead, after the second magnetic attraction parts 208 and the fourth magnetic attraction part 212 are formed, multiple conductive pillars 500 are formed in the grooves O1 as shown in FIG. 1A and FIG. 1B, and the conductive pillars 500 penetrate through the second magnetic attraction parts 208, respectively, and then the electronic component 400 is adhered to the connecting layer 600, so that the electronic component 400 is electrically connected to the conductive pillars 500.

After the electronic component 400 is adhered to the connecting layer 600, the second memory metal layer 204 is disposed on the first memory metal layer 202, so that the first magnetic attraction parts 206 and the second magnetic attraction parts 208 are mutually attracted to each other and are in contact with each other, and the third magnetic attraction part 210 and the fourth magnetic attraction part 212 are attracted to each other and are in contact with each other, thereby forming the circuit board 10 as shown in FIG. 1A and FIG. 1B.

In summary, as exemplified in at least one embodiment of the present disclosure, when experiencing excessive temperature, the circuit board and its manufacturing method disclosed herein includes a temperature control element which can disconnect the electronic component from the pads of the wiring base. This then functions to provide protection against overheating and reduce the damages caused by high temperature, thereby contributing to improve reliability and increase product life.

Although the present disclosure has been described in considerable details with reference to certain embodiments thereof, other embodiments are possible. Therefore, the spirit and scope of the appended claims should not be limited to the descriptions of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A circuit board, comprising:
a wiring base, comprising a plurality of pads;
a temperature control element, disposed on the wiring base and forming a gap with the wiring base, wherein the temperature control element comprises:
a first memory metal layer;
a second memory metal layer, fixed on the first memory metal layer, wherein the first memory metal layer is located between the second memory metal layer and the wiring base;
a plurality of first magnetic attraction parts, disposed in the first memory metal layer; and
a plurality of second magnetic attraction parts, disposed in the second memory metal layer and corresponding to the first magnetic attraction parts, respectively;
a plurality of flexible parts, disposed in the gap and corresponding to the first magnetic attraction parts, respectively, wherein the flexible parts are electrically connected to the pads, respectively;
an electronic component, disposed on the temperature control element; and
a plurality of conductive pillars, disposed between the electronic component and the temperature control element, wherein the conductive pillars penetrate the second magnetic attraction parts respectively and are electrically connected to the electronic component.

2. The circuit board of claim 1, wherein a transformation temperature of the first memory metal layer is the same as a transformation temperature of the second memory metal layer.

3. The circuit board of claim 1, wherein a bending direction of the first memory metal layer is opposite to a bending direction of the second memory metal layer.

4. The circuit board of claim 1, wherein the temperature control element further comprises:
a third magnetic attraction part, disposed in the first memory metal layer and located between adjacent two of the first magnetic attraction parts, wherein a width of the third magnetic attraction part is greater than a width of each of the first magnetic attraction parts; and
a fourth magnetic attraction part, disposed in the second memory metal layer and located between adjacent two of the second magnetic attraction parts, wherein a width of the fourth magnetic attraction part is greater than a width of each of the second magnetic attraction parts.

5. The circuit board of claim 4, wherein the third magnetic attraction part and the fourth magnetic attraction part are attracted to each other and are in contact with each other to fix the second memory metal layer on the first memory metal layer.

6. The circuit board of claim 5, wherein while the second memory metal layer is not bent relative to the first memory metal layer, the first memory metal layer and the second memory metal layer are in contact with each other to make the first magnetic attraction parts and the second magnetic attraction parts be attracted to each other and be in contact with each other, and the conductive pillars be in contact with the flexible parts, respectively.

7. The circuit board of claim 5, wherein while the second memory metal layer is bent relative to the first memory metal layer, the first memory metal layer and the second memory metal layer are partially separated to make the first magnetic attraction parts and the second magnetic attraction parts become separated from each other, and the conductive pillars become separated from the flexible parts.

8. The circuit board of claim 1, wherein the wiring base further comprises an insulating layer, wherein the pads are embedded in the insulating layer.

9. The circuit board of claim 8, wherein a top surface of each of the pads is flush with a top surface of the insulating layer.

10. The circuit board of claim 1, wherein each of the flexible parts comprises a conductive portion and an outer portion surrounding the conductive portion, wherein the conductive portions penetrate the first magnetic attraction parts, respectively, and are electrically connected to the pads, respectively.

11. The circuit board of claim 1, further comprising a connecting layer disposed between the temperature control element and the electronic component, wherein the conductive pillars penetrate the connecting layer.

12. The circuit board of claim 1, wherein a material of the first memory metal layer and a material of the second memory metal layer comprise nickel-titanium alloy.

13. The circuit board of claim 1, wherein a material of the flexible parts comprises conductive fibers.

14. The circuit board of claim 1, wherein a material of the conductive pillars comprises copper.

15. A method of manufacturing a circuit board, comprising:
providing a first sacrificial layer and a conductive layer, wherein the first sacrificial layer is located on the conductive layer;
patterning the first sacrificial layer to form a plurality of first trenches;
forming a plurality of conductive portions in the first trenches;
after the conductive portions are formed, patterning the conductive layer to form a plurality of pads;
after the pads are formed, laminating a build-up structure on the pads and patterning the build-up structure to form a plurality of second trenches;
forming a plurality of wiring structures in the second trenches;
after the wiring structures are formed, removing the first sacrificial layer to expose a sidewall of each of the conductive portions;
after the first sacrificial layer is removed, forming a plurality of outer portions surrounding the conductive portions, respectively, to form a plurality of flexible parts;
forming a second sacrificial layer to surround the flexible parts;
forming a plurality of first magnetic attraction parts corresponding to the flexible parts, respectively, and a third magnetic attraction part located on the second sacrificial layer;
forming a first memory metal layer on the second sacrificial layer to surround the first magnetic attraction parts and the third magnetic attraction part;
after the first memory metal layer is formed, removing the second sacrificial layer to form a gap;
providing an initial connecting layer and a second initial memory metal layer, wherein the initial connecting layer is located on the second initial memory metal layer;
patterning the initial connecting layer and the second initial memory metal layer to form a connecting layer and a second memory metal layer, wherein the connecting layer has a plurality of grooves and the second memory metal layer has a plurality of openings;
forming a plurality of second magnetic attraction parts and a fourth magnetic attraction part in the openings;
after the second magnetic attraction parts and the fourth magnetic attraction part are formed, adhering an electronic component to the connecting layer; and
after the electronic component is adhered to the connecting layer, disposing the second memory metal layer on the first memory metal layer to make the first magnetic attraction parts and the second magnetic attraction parts become attracted to each other and be in contact with each other, and the third magnetic attraction part and the fourth magnetic attraction part become attracted to each other and be in contact with each other.

16. The method of manufacturing the circuit board of claim 15, wherein the electronic component comprises a plurality of pins, the pins are inserted in the grooves, respectively, and penetrate the second magnetic attraction parts, respectively.

17. The method of manufacturing the circuit board of claim 15, further comprising:
after the second magnetic attraction parts and the fourth magnetic attraction part are formed, and before the electronic component is adhered to the connecting layer, forming multiple conductive pillars in the grooves, wherein the conductive pillars penetrate through the second magnetic attraction parts, respectively.
